(19) United States
(12) Patent Application Publication
(10) Pub. No.: US 2026/0231335 A1
(43) Pub. Date: Aug. 6, 2026

(54) HIGH CURRENT DENSITY POWER MODULE

(71) Applicant: Monolithic Power Systems, Inc., San Jose, CA (US)

(72) Inventors: Ting GE, San Jose, CA (US); Eric NGUYEN, San Jose, CA (US)

(21) Appl. No.: 19/578,695

(22) Filed: Mar. 25, 2026

Related U.S. Application Data
(63) Continuation-in-part of application No. 18/785,452, filed on Jul. 26, 2024.

(51) Int. Cl. H05K 1/181; H01F 27/24; H01F 27/29; H02M 3/00; H05K 3/28; H05K 3/303

(52) U.S. Cl. CPC H05K 1/181; H01F 27/24; H01F 27/292; H05K 3/28; H05K 3/303; H02M 3/003; H05K 2201/1003

(57) ABSTRACT

A power block includes an inductor unit disposed between two substrates, with power stage integrated circuits on one substrate and components on both substrates. A molding compound encapsulates the inductor unit and is ground to provide a planar surface with coplanar contact pads for reliable assembly. The molding compound includes cavities adjacent to the inductor unit to accommodate components. On each side of the inductor unit, one set of components is embedded in the molding compound and another set is disposed in the cavities. The cavities may be formed by drilling into the molding compound after molding, or by using a mold that directly defines the cavity shape. Multiple power blocks may share common substrates and a continuous molding compound, with adjacent power blocks sharing a common cavity.

### CROSS-REFERENCE TO RELATED APPLICATION

The present application is a continuation-in-part of U.S. application Ser. No. 18/785,452, filed on Jul. 26, 2024, which is incorporated herein by reference in its entirety.

### TECHNICAL FIELD

The present disclosure is directed to electrical circuits.

### BACKGROUND

Power modules comprise electrical circuits that perform power conversion, such as DC-DC converters, AC-DC converters, etc. To minimize footprint, a power module may include a DrMOS (Driver and MOSFET) module, which integrates a gate driver, high-side MOSFET, and low-side MOSFET in a single package. Power modules are relatively compact in size, making them advantageous in space-critical power supplies.

Current density refers to the amount of electrical current flowing per unit area of the power module. For a two-phase power module, the current density is usually limited by the maximum current of the DrMOS and footprint of the power module. For example, a two-phase power module with a DrMOS that can handle 60 A current and has dimensions of 9 mm×10 mm, the current density is 60*2/(9*10)=1.33 A/mm2. The current density of existing power modules needs to be enhanced in order to meet the growing demands of high-current power supply applications.

### BRIEF SUMMARY

In one embodiment, a power block of a power converter includes a first substrate having one or more power stage integrated circuits disposed on a first side, a second substrate with a first side facing a second side of the first substrate, and an inductor unit disposed between the first and second substrates. The inductor unit comprises a magnetic core and a winding embedded within the magnetic core, with the winding having a first end electrically connected to a contact pad on a first side of the inductor unit that interfaces with the first substrate and a second end electrically connected to a contact pad on a second side of the inductor unit that interfaces with the second substrate. A molding compound is disposed between the first and second substrates and at least partially encapsulates the inductor unit, the molding compound having one or more cavities in regions adjacent to the inductor unit. A first set of components is embedded in the molding compound and a second set of components is disposed in the one or more cavities.

In another embodiment, a method of manufacturing a power block of a power converter includes mounting an inductor unit and a first set of components on a first side of a first substrate, performing a molding step to encapsulate the inductor unit and the first set of components in a molding compound, performing a grinding step to grind down the molding compound to a first side of the inductor unit to planarize the surface and expose contact pads, forming one or more cavities in the molding compound in regions adjacent to the inductor unit, and assembling a second substrate onto the inductor unit with a second set of components being received in the one or more cavities. One or more power stage integrated circuits are disposed on one of the first substrate and the second substrate.

In yet another embodiment, a power module includes a first substrate having one or more power stage integrated circuits disposed on a first side, a second substrate with a first side facing a second side of the first substrate, and two or more inductor units disposed between the first and second substrates. A molding compound is disposed between the first and second substrates and at least partially encapsulates the two or more inductor units, the molding compound having one or more cavities in regions adjacent to the two or more inductor units. A first set of components is embedded in the molding compound and a second set of components is disposed in the one or more cavities.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. For ease of illustration, not every instance of a repeated element is labeled in the drawings; such elements are readily identifiable from the drawings and their context. The drawings are not necessarily to scale.

FIG. 1 shows an electrical schematic diagram of a power converter, in accordance with an embodiment of the present invention.

FIG. 2 shows an electrical schematic diagram of a power converter, in accordance with another embodiment of the present invention.

FIG. 3 shows a side view of a physical layout of a power block, in accordance with an embodiment of the present invention.

FIG. 4 shows a planar view of a top side of a substrate of the power block of FIG. 3, in accordance with an embodiment of the present invention.

FIG. 5 shows a planar view of a top side of an inductor unit of the power block of FIG. 3, in accordance with an embodiment of the present invention.

FIG. 6 shows a planar view of a bottom side of an inductor unit of the power block of FIG. 3, in accordance with an embodiment of the present invention.

FIG. 7 shows a planar view of a bottom side of an inductor unit of the power block of FIG. 3, in accordance with another embodiment of the present invention.

FIG. 8 shows a three-dimensional (3D) transparent view of the power block of FIG. 3, in accordance with an embodiment of the present invention.

FIG. 9 shows a 3D transparent view of the inductor unit of the power block of FIG. 3, in accordance with an embodiment of the present invention.

FIGS. 10, 11, and 12 show additional 3D transparent views of the inductor unit of the power block of FIG. 3, in accordance with an embodiment of the present invention.

FIG. 13 shows a 3D transparent view of the inductor unit of the power block of FIG. 3, in accordance with another embodiment of the present invention.

FIGS. 14 and 15 show additional 3D transparent views of the inductor unit of the power block of FIG. 3, in accordance with another embodiment of the present invention.

FIG. 16 shows a 3D transparent view of a power module that comprises a plurality of power blocks, in accordance with an embodiment of the present invention.

FIG. 17 shows a planar view of bottom sides of substrates in the power module of FIG. 16, in accordance with an embodiment of the present invention.

FIG. 18 shows a side view of a physical layout of a power block, in accordance with another embodiment of the present invention.

FIG. 19 shows a side view of the power block of FIG. 18, in accordance with an embodiment of the present invention.

FIG. 20 shows a planar view of a top side of an inductor unit of the power block of FIG. 18, in accordance with an embodiment of the present invention.

FIG. 21 shows a planar view of a bottom side of an inductor unit of the power block of FIG. 18, in accordance with an embodiment of the present invention.

FIG. 22 shows a planar view of a top side of a substrate of the power block of FIG. 18, in accordance with an embodiment of the present invention.

FIG. 23 shows a side view of a physical layout of a power block, in accordance with an embodiment of the present invention.

FIG. 24 shows a 3D view of the power block of FIG. 23, in accordance with an embodiment of the present invention.

FIG. 25 shows a 3D view of the power block of FIG. 23, in accordance with an embodiment of the present invention.

FIGS. 26-29 are side views illustrating a method of manufacturing the power block of FIG. 23, in accordance with an embodiment of the present invention.

FIG. 30 shows a side view of a physical layout of a power block, in accordance with an embodiment of the present invention.

FIG. 31 shows a side view of a physical layout of a power module comprising two or more power blocks of FIG. 30, in accordance with an embodiment of the present invention.

### DETAILED DESCRIPTION

In the present disclosure, numerous specific details are provided, such as examples of circuits, components, and structures, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

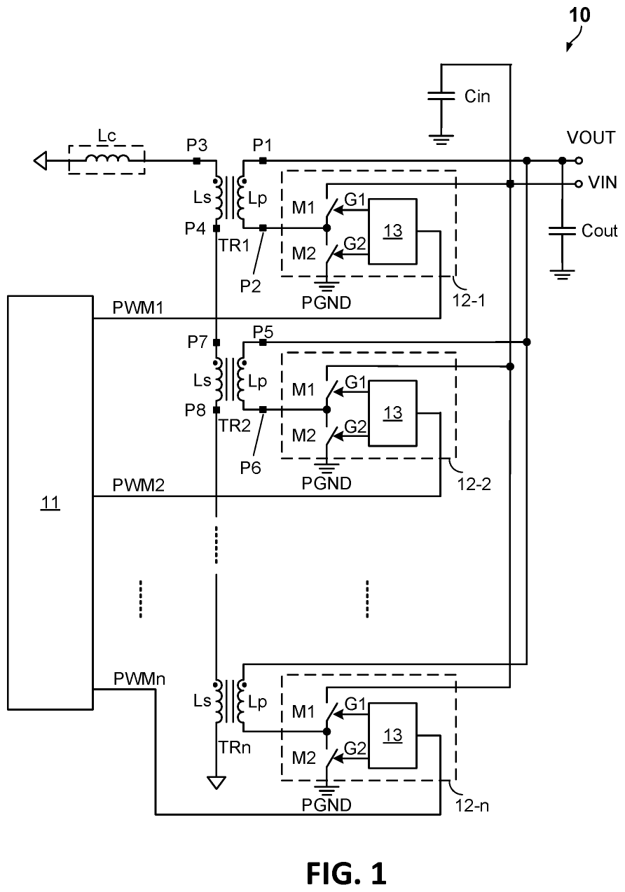

FIG. 1 shows an electrical schematic diagram of a power converter 10, in accordance with an embodiment of the present invention. In the example of FIG. 1, the power converter 10 comprises a multiphase trans-inductor voltage regulator (TLVR). Generally, a TLVR is a type of voltage regulator that uses a winding of a transformer as an output inductor. In a multiphase TLVR, a winding of a transformer is employed as an output inductor of an output phase (“phase”), and the other windings of the transformers of all the phases are connected in a series loop to ground. Because of the series connection of the other windings, all of the phases are able to respond to a change in load current, allowing for a faster transient response compared to other types of voltage regulators.

The power converter 10 comprises a plurality of power stage integrated circuits (ICs) 12 (i.e., 12-1, 12-2, . . . , 12-n). Each power stage IC 12 comprises a driver 13, a high-side switch M1, and a low-side switch M2. In one embodiment, each power stage IC 12 is a DrMOS, wherein each of the switches M1 and M2 is a metal-oxide-semiconductor field-effect transistor (MOSFET) and the driver 13 is a gate driver that is integrated with the switches M1 and M2 in the same package.

In the example of FIG. 1, the high-side switch M1 receives an input voltage VIN. The driver 13 generates gate signals G1 and G2 that drive the gates of the switch M1 and switch M2, respectively, in accordance with a pulse width modulation (PWM) control signal (i.e., PWM1, PWM2, . . . , PWMn) from a PWM controller 11 to generate an output voltage VOUT. An output capacitor Cout is connected to the output voltage VOUT and an input capacitor Cin is connected to the input voltage VIN.

Each power stage IC 12 generates a phase of the output voltage VOUT of the power converter 10. In the example of FIG. 1, the power stage IC 12-1 generates a first phase of the output voltage VOUT, the power stage IC 12-2 generates a second phase of the output voltage VOUT, etc. The high-side switches of the power stage ICs 12 are connected to an input voltage VIN, and the low-side switches of the power stage ICs 12 are connected to ground. The PWM signals are interleaved to drive the power stage ICs 12 to generate the output voltage VOUT.

Each power stage IC 12 has a corresponding transformer TR (i.e., TR1, TR2, . . . , TRn). A transformer TR has a primary winding Lp and a secondary winding Ls. In the example of FIG. 1, the primary winding Lp of the first phase has a first end P1 and a second end P2, the secondary winding Ls of the first phase has a first end P3 and a second end P4, the primary winding Lp of the second phase has a first end P5 and a second end P6, the secondary winding Ls of the second phase has a first end P7 and a second end P8, etc.

In the power converter 10, a primary winding Lp serves as the output inductor of the phase. That is, the primary winding Lp is connected to a switch node (e.g., see node P2) formed by the pair of switches M1 and M2, and the output current of the power stage IC 12 flows through the primary winding Lp. The secondary windings Ls are connected in series. A trans-inductor loop is formed by connecting an optional compensation inductor Lc in series with the secondary windings Ls. Each of the input capacitor Cin and output capacitor Cout may comprise a plurality of capacitors that are connected in parallel, for example.

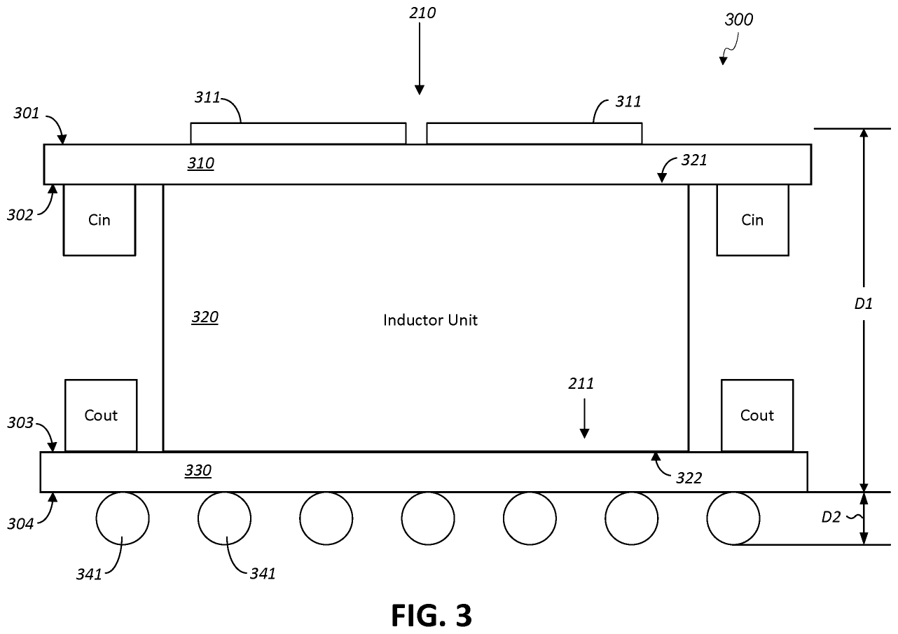

In one embodiment, the power converter 10 includes an inductor unit (e.g., see FIGS. 3, 320) containing one or more transformers TR, a first substrate (e.g., FIGS. 3, 310) that supports one or more power stage ICs 12, and a second substrate (e.g., FIGS. 3, 330) that supports other components (e.g., the PWM controller 11) of the power converter 10. The inductor unit also provides vias that electrically connect corresponding nodes on the first and second substrates. The input capacitor Cin may be disposed on a bottom side of the first substrate, and the output capacitor Cout may be disposed on a top side of the second substrate.

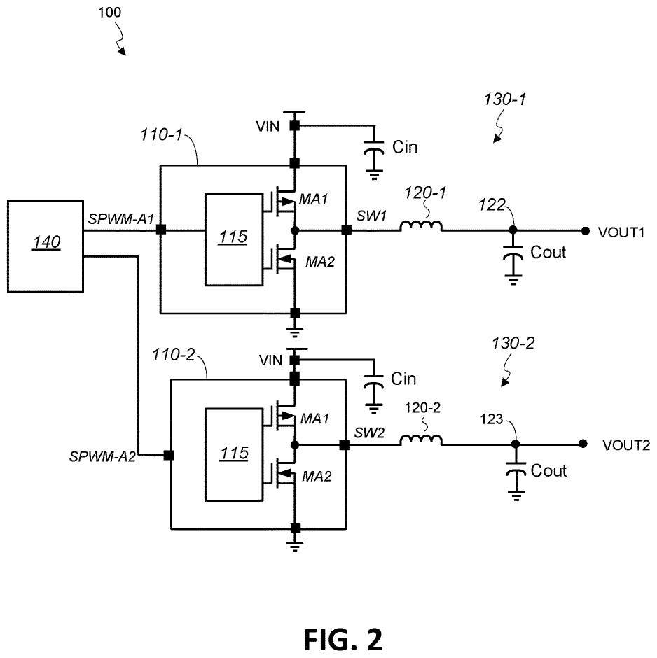

FIG. 2 shows an electrical schematic diagram of a power converter 100 in accordance with an embodiment of the present invention. In the example of FIG. 2, the power converter 100 has two regulators 130 (i.e., 130-1, 130-2), with each regulator 130 comprising an output inductor 120 (i.e., 120-1, 120-2) and a power stage IC 110 (i.e., 110-1, 110-2). In the example of FIG. 2, a regulator 130 is a buck converter. As can be appreciated, a regulator 130 may also be configured as a boost converter or other type of power converter depending on the application.

Each of the regulators 130-1 and 130-2 receives an input voltage VIN to generate an output voltage VOUT (i.e., VOUT1, VOUT2). The output voltages of the regulators 130-1 and 130-2 may be connected together and interleaved to generate a multiphase output voltage. For example, an output voltage node 122 and an output voltage node 123 may be connected together, with each regulator 130 providing a phase of a multiphase output voltage. Generally, the power converter 100 may include additional regulators 130 to generate additional output voltages or phases.

Each power stage IC 110 has, integrated therein, a driver 115, a high-side switch MA1, and low-side switch MA2. In one embodiment, each power stage IC 110 is a DrMOS, wherein each of the switches MA1 and MA2 is a MOSFET and the driver 115 is a gate driver that is integrated with the switches MA1 and MA2. In the example of FIG. 2, a power stage IC has a first pin for receiving a PWM signal (SPWM-A1, SPWM-A2), a second pin for receiving an input voltage VIN, a third pin for connecting to ground, and a fourth pin that is connected to a switch node SW (SW1, SW2) formed by the pair of switches MA1 and MA2. The drain of the switch MA1 is connected to the input voltage VIN and the source of the switch MA2 is connected to ground. The source of the switch MA1 is connected to the drain of the switch MA2 at the switch node SW. A PWM controller 140 generates PWM signals (SPWM-A1, SPWM-A2). The driver 115 turns the switches MA1 and MA2 ON and OFF in accordance with the PWM signal to generate the output voltage VOUT.

In the example of FIG. 2, a first end of an output inductor 120 is connected to the switch node SW and a second end of the output inductor 120 is connected to the output voltage VOUT. An input capacitor Cin is connected to the input voltage VIN, and an output capacitor Cout is connected to the output voltage VOUT. Each of the input capacitor Cin and output capacitor Cout may comprise a plurality of capacitors that are connected in parallel, for example.

In one embodiment, the power converter 100 includes an inductor unit (e.g., see FIGS. 3, 320) containing one or more output inductors 120, a first substrate (e.g., FIGS. 3, 310) that supports one or more power stage ICs 110, and a second substrate (e.g., FIGS. 3, 330) that supports other components (e.g., a PWM controller 140) of the power converter 100. The inductor unit also provides vias that electrically connect nodes between the first and second substrates. The input capacitor Cin may be disposed on a bottom side of the first substrate, and the output capacitor Cout may be disposed on a top side of the second substrate.

FIG. 3 shows a side view of a physical layout of a power block 300, in accordance with an embodiment of the present invention. FIG. 3 is not drawn to scale. The power block 300 may comprise the power converter 10 of FIG. 1, power converter 100 of FIG. 2, or other power converter. The power block 300 comprises an inductor unit 320, a substrate 310 that supports one or more power stage ICs 311, and an underlying substrate 330 that supports other components of the power converter.

In one embodiment, the substrate 310 is a printed circuit board (PCB). The substrate 310 has a top side 301 and a bottom side 302. One or more input capacitors Cin are disposed on the bottom side 302, and one or more power stage ICs 311 are disposed on the top side 301. The dies of the power stage ICs 311 are depicted as being separate, but they can also be molded together. An input capacitor Cin and an output capacitor Cout may be a 0201 capacitor, a 0402 capacitor, a 0603 capacitor, a 0805 capacitor, or other suitably sized capacitor. In one embodiment, each of the power stage ICs 311 is a DrMOS. The input capacitors Cin may be disposed along an outside perimeter of the substrate 310 on the bottom side 302. Similarly, the output capacitors Cout may be disposed along an outside perimeter of the underlying substrate 330 on the top side 303.

Placing the power stage ICs 311 on the top side 301 advantageously improves heat dissipation. Furthermore, disposing the input capacitors Cin on the bottom side 302 allows for more active components to be disposed on the top side 301, thereby enhancing the current density of the power block 300. In one embodiment, a vertical dimension D1 from the bottom side 304 to a topmost surface on the substrate 310 is about 3.8 mm (plus or minus 0.2 mm), and a thickness D2 of a ball grid array (BGA) ball 341 is about 0.5 mm.

In one embodiment, the inductor unit 320 comprises a magnetic core, transformers or inductors (depending on circuit topology) that are embedded within the magnetic core, and a plurality of vias that are embedded within or attached to the magnetic core. The inductor unit 320 has a top side 321 that interfaces with the bottom side 302 of the substrate 310 and a bottom side 322 that interfaces with the top side 303 of the underlying substrate 330. In one embodiment, the top side 321 is the top surface of the magnetic core and the bottom side 322 is the bottom surface of the magnetic core. Vias electrically connect contact pads on the top side 321 of the inductor unit 320 to contact pads on the bottom side 322 of the inductor unit 320. A via may comprise a metal structure that is coated with an electrically insulating material. Similarly, inductor coils and transformer windings embedded within the magnetic core may be coated with electrical insulators.

FIG. 3 also shows viewing reference arrows 210 and 211 that are referred to later below. Note that the bottom side 302 of the substrate 310 and the top side 303 of the underlying substrate 330 face toward each other.

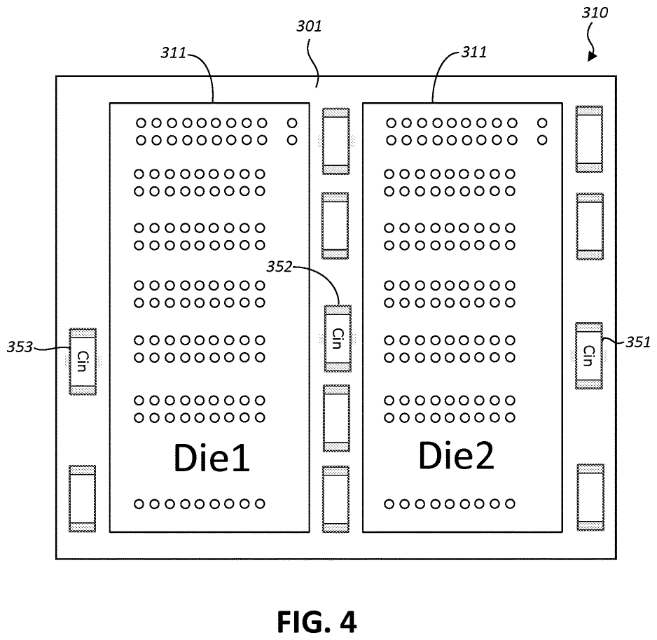

FIG. 4 shows a planar view of the top side 301 of the substrate 310, in accordance with an embodiment of the present invention. FIG. 4 is as seen in the direction of arrow 210 shown in FIG. 3 and through the substrate 310 to show the capacitors Cin that are on the bottom side 302. FIG. 4 shows the die of each of the power stage ICs 311. The circles within a die of a power stage IC 311 represent nodes to circuits that are integrated in the power stage IC 311. Input capacitors Cin (see FIG. 4, 351-353) and other capacitors are disposed along the outside perimeter of the substrate 310 on the bottom side 302.

Referring to FIG. 3, in one embodiment, the underlying substrate 330 is a PCB. Disposed on the underlying substrate 330 are other components of the power converter, such as a PWM controller. BGA balls 341 on the bottom side 304 of the underlying substrate 330 allow the power block 300 to be soldered on another substrate, such as a motherboard. Several power blocks 300 may be disposed on the motherboard depending on the needs of the power supply application. For example, each power block 300 may generate two phases of an output voltage VOUT, and 16 power blocks 300 may be disposed on the motherboard to generate 32 phases of the output voltage VOUT.

One or more power blocks 300 may be packaged together in the same power module. For example, instead of having 16 power blocks 300 that each has a separate underlying substrate 330, all of the power blocks 300 may share the same underlying substrate 330 to form a power module with 16 power blocks that generate 32 phases. As another example, 4 power blocks 300 may share the same underlying substrate 330 to form a power module with 8 phases. As can be appreciated, each power block may have more than two phases to form a power module with even more phases.

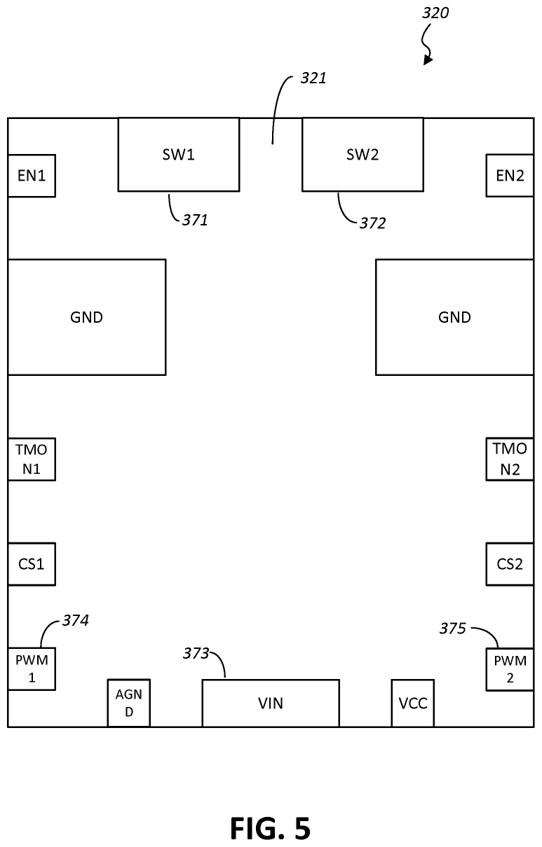

FIG. 5 shows a planar view of the top side 321 of the inductor unit 320, in accordance with an embodiment of the present invention. FIG. 5 show contact pads of the inductor unit 320 that interface with corresponding contact pads on the bottom side 302 of the substrate 310 to electrically connect to corresponding nodes on the power stage ICs 311. In the example of FIG. 5, the contact pad 371 electrically connects to a switch node (e.g., FIG. 1, node P2; FIG. 2, SW1), the contact pad 372 electrically connects to another switch node (e.g., FIG. 1, node P6; FIG. 2, SW2), the contact pad 373 electrically connects to the input voltage VIN, the contact pad 374 electrically connects to the gates of a pair of high-side and low-side switches, and the contact pad 375 electrically connects to the gates of another pair of high-side and low side switches.

In one embodiment, output inductors and primary windings that are embedded within the inductor unit 320 have ends that are on opposite sides of the inductor unit 320. More particularly, in a power converter with TLVR circuit topology, a primary winding of a transformer or an inductor that is embedded within the inductor unit 320 has a first end that is electrically connected to a switch node contact pad 371/372 on the top side 321 and second end that is electrically connected to an output voltage contact pad on the bottom side 322.

FIG. 5 shows other contact pads, such as contact pads for enabling the pairs of high-side and low-side switches (“EN1”, “EN2”), contact pads for monitoring temperature (“TMO N1”, TMO N2”), contact pads for monitoring current (“CS1”, “CS2”), contact pads for ground connections, contact pads for VCC, etc. Contact pads on the top side 321 may electrically connect to contact pads on the bottom side 322 by way of vias that that are attached to or embedded within the inductor unit 320.

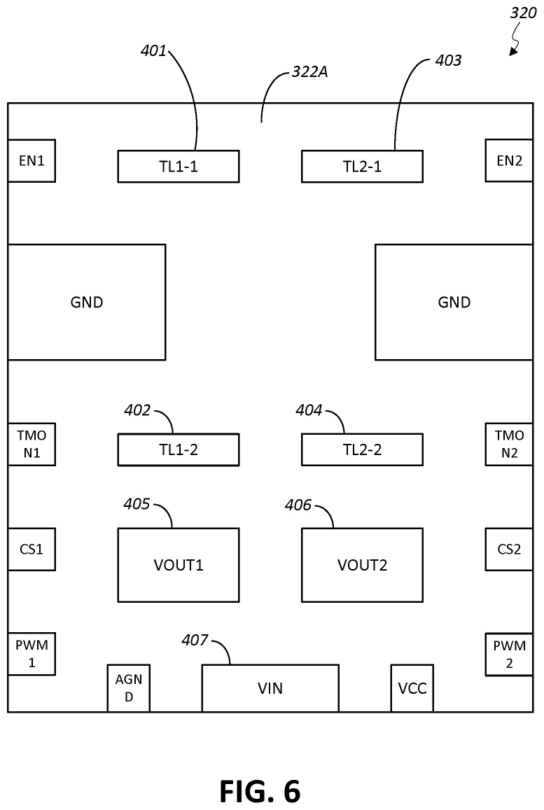

FIG. 6 shows a planar view of a bottom side 322A of the inductor unit 320, in accordance with an embodiment of the present invention. The bottom side 322A is a particular implementation of the bottom side 322 of the inductor unit 320 in the case where the inductor unit 320 has embedded transformers, such as transformers in a TLVR circuit topology (e.g., see FIG. 1, transformers TR). FIG. 6 shows the bottom side 322A as seen in the direction of the arrow 211 in FIG. 3 through the substrate 310 and the inductor unit 320, i.e., as seen from the top with the substrate 310 and the rest of the inductor unit 320 being transparent.

FIG. 6 shows contact pads of the inductor unit 320 that interface with corresponding contact pads on the top side 303 of the underlying substrate 330 to electrically connect to corresponding nodes of circuits on the underlying substrate 330 or other substrate. In the example of FIG. 6, the contact pad 401 electrically connects to a first end of a secondary winding (e.g., at node P3 shown in FIG. 1) of a first transformer (e.g., transformer TR1 shown in FIG. 1) embedded in the inductor unit 320; the contact pad 402 electrically connects to a second end of the secondary winding (e.g., at node P4 shown in FIG. 1) of the first transformer; the contact pad 403 electrically connects to a first end of a secondary winding (e.g., at node P7 shown in FIG. 1) of a second transformer (e.g., transformer TR2 shown in FIG. 1) embedded in the inductor unit 320; the contact pad 404 electrically connects to a second end of the secondary winding (e.g., at node P8 shown in FIG. 1) of the second transformer; the contact pad 405 electrically connects to the output voltage VOUT and to a second end of a primary winding of the first transformer (e.g., at node P1/output voltage node shown in FIG. 1); the contact pad 406 electrically connects to another output voltage VOUT and to a second end of a primary winding of the second transformer (e.g., at node P5/output voltage node shown in FIG. 1); and the contact pad 407 electrically connects to the input voltage VIN. FIG. 6 shows other contact pads that electrically connect to corresponding contact pads on the top side 321 of the inductor unit 320 by way of vias.

In one embodiment, the primary winding of a transformer embedded within the inductor unit 320 has a first end that is connected to a contact pad on the top side 321 and a second end that is connected to a contact pad on the bottom side 322A. That is, the primary winding has opposing ends that are on opposite sides of the inductor unit 320. More particularly, a primary winding has one end that is electrically connected to a switch node pad on the top side 321 (e.g., FIG. 5, contact pad 371) and an opposing end that is electrically connected to the output voltage VOUT on the bottom side 322A (e.g., FIG. 6, contact pad 405). Both ends of the secondary winding of the transformer are electrically connected to corresponding contact pads on the bottom side 322A (e.g., FIG. 6, contact pads 401 and 402).

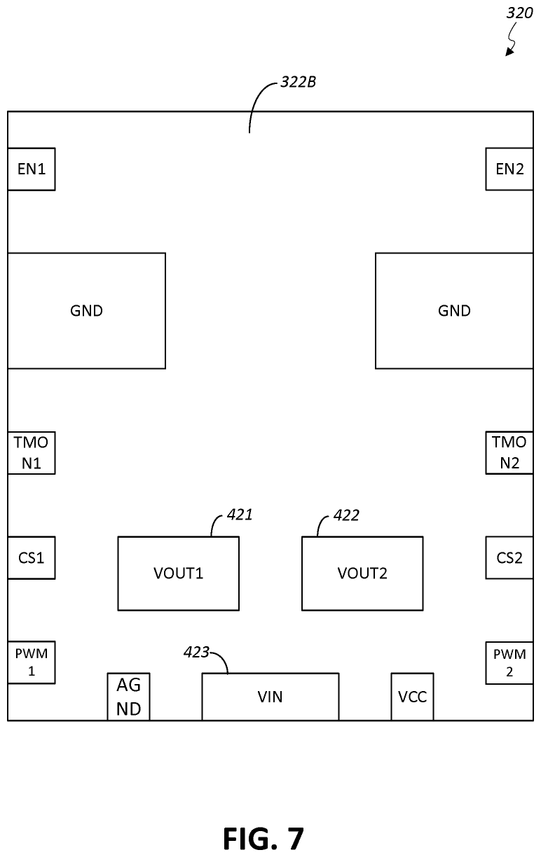

FIG. 7 shows a planar view of a bottom side 322B of the inductor unit 320, in accordance with an embodiment of the present invention. The bottom side 322B is a particular implementation of the bottom side 322 of the inductor unit 320 in the case where the inductor unit 320 has an inductor (e.g., see FIG. 2, output inductor 120), instead of a transformer, in a non-TLVR circuit topology. FIG. 7 shows the bottom side 322B as seen in the direction of the arrow 211 in FIG. 3 through the substrate 310 and the inductor unit 320, i.e., as seen from the top with the substrate 310 and the rest of the inductor unit 320 being transparent.

FIG. 7 shows contact pads of the inductor unit 320 that interface with corresponding contact pads on the top side 303 of the underlying substrate 330 to electrically connect to corresponding nodes of circuits on the underlying substrate 330 or other substrate. In the example of FIG. 7, the contact pad 421 electrically connects to an output voltage VOUT and to a second end of a first inductor (e.g., at node 122 shown in FIG. 2) that is embedded within the inductor unit 320; the contact pad 422 electrically connects to another output voltage VOUT and to a second end of a second inductor that is embedded within the inductor unit 320 (e.g., at node 123 shown in FIG. 2); and the contact pad 423 electrically connects to the input voltage VIN. FIG. 7 shows other contact pads that electrically connect to corresponding contact pads on the top side 321 by way of vias.

In one embodiment, an inductor that is embedded within the inductor unit 320 has a first end that is connected to a contact pad on the top side 321 and a second end that is connected to a contact pad on the bottom side 322B. That is, the embedded inductor has ends that are on opposite sides of the inductor unit 320. More particularly, an embedded inductor has one end that is electrically connected to a switch node pad on the top side 321 (e.g., FIG. 5, contact pad 371) and an opposing end that is electrically connected to the output voltage VOUT on the bottom side 322B (e.g., FIG. 7, contact pad 421).

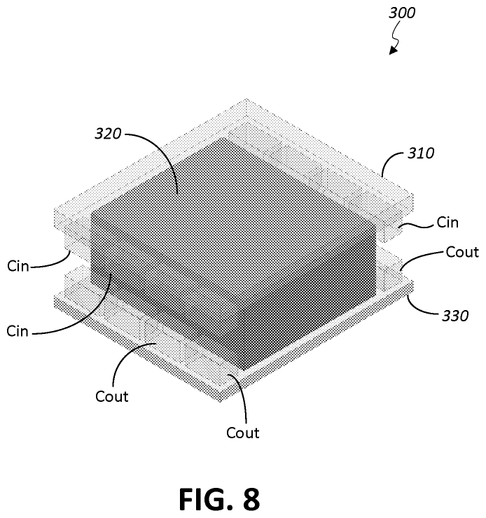

FIG. 8 shows a three-dimensional (3D) transparent view of the power block 300, in accordance with an embodiment of the present invention. In FIG. 8, components other than the inductor unit 320 and the underlying substrate 330 are transparent for clarity of illustration. As shown in FIG. 8, the capacitors Cin are disposed on the bottom side of the substrate 310 and the capacitors Cout are disposed on the top side of the underlying substrate 330. The capacitors Cin and Cout may be disposed along the perimeter of their respective substrates.

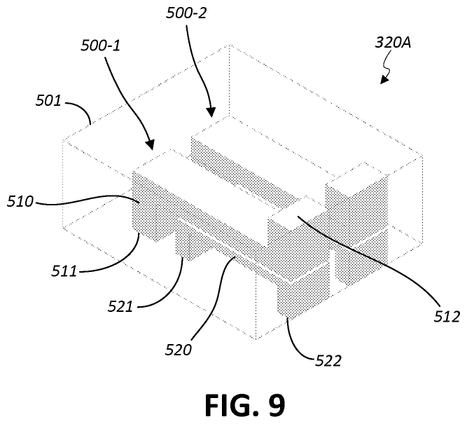

FIG. 9 shows a 3D transparent view of an inductor unit 320A, in accordance with an embodiment of the present invention. The inductor unit 320A is an implementation of the inductor unit 320 for a TLVR circuit topology (e.g., see FIG. 1). More particularly, the inductor unit 320A has transformers 500 (i.e., 500-1, 500-2) that are embedded in a magnetic core 501. The inductor unit 320A is depicted as having two transformers 500 for illustration purposes only. Additional transformers 500 may be embedded within the magnetic core 501 to meet the needs of a particular power supply application, such as to add more phases. In the example of FIG. 9, the top side of the inductor unit 320A is the top surface of the magnetic core 501, and the bottom side of the inductor unit 320A is the bottom surface of the magnetic core 501. In one embodiment, the magnetic core 501 is a rectangular block of magnetic material, such as a ferromagnetic material that has high magnetic permeability or powder iron with high saturation flux density.

In the example of FIG. 9, a transformer 500 comprises a primary winding 510 and a secondary winding 520 that are separated by a portion of the magnetic core 501. In one embodiment, each of the primary winding 510 and secondary winding 520 has a single turn. The primary winding 510 has a first end 512 that is electrically connected to a contact pad on the top side of the inductor unit 320A and a second end 511 that is electrically connected to a contact pad on the bottom side of the inductor unit 320A. The secondary winding 520 has a first end 521 and a second end 522 that are electrically connected to corresponding contact pads on the bottom side of the inductor unit 320A.

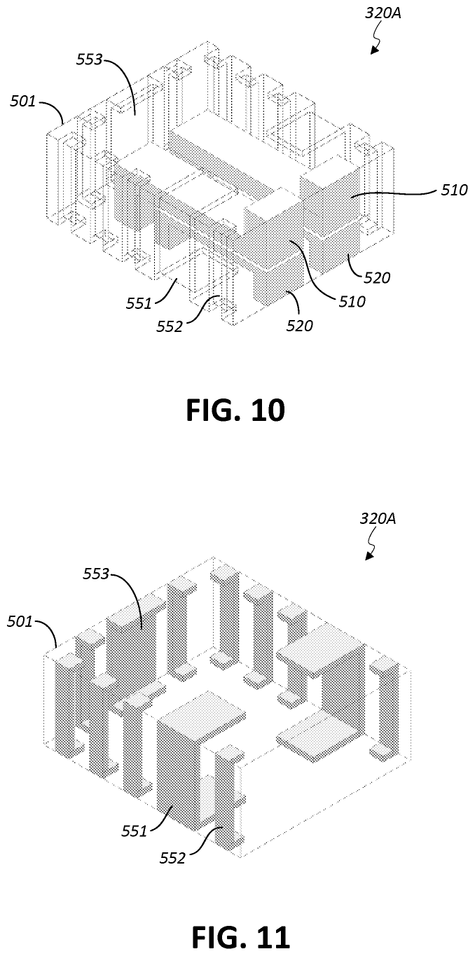

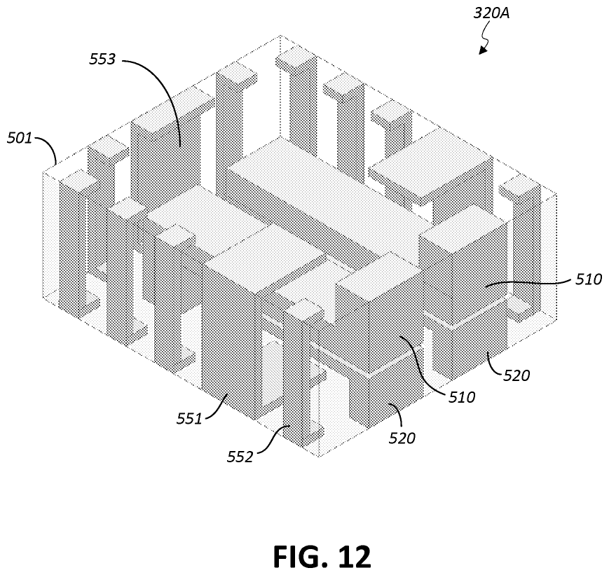

FIGS. 10, 11, and 12 show additional 3D transparent views of the inductor unit 320A, in accordance with an embodiment of the present invention. The transformers 500, each comprising a primary winding 510 and a secondary winding 520, are not shown in FIG. 11 to better show the vias.

Referring to FIGS. 10-12, a via goes from the top surface to the bottom surface of magnetic core 501. A via may be attached to the magnetic core 501 as depicted in FIGS. 10-12 or embedded within the magnetic core 501. As an example, a via 551 electrically connects a ground reference from a contact pad on the top surface (see FIG. 5, GND contact pad) to a contact pad on the bottom surface (see FIG. 6, GND contact pad) of the magnetic core 501. As another example, a via 552 electrically connects an enable signal from a contact pad on the top surface (e.g., FIG. 5, EN2 contact pad) to a contact pad on the bottom surface (e.g., see FIG. 6, EN2 contact pad) of the magnetic core 501. Yet another example, a via 553 electrically connects the input voltage from a contact pad on the top surface (e.g., FIG. 5, contact pad 373) to a contact pad on the bottom surface (e.g., see FIG. 6, contact pad 407) of the magnetic core 501.

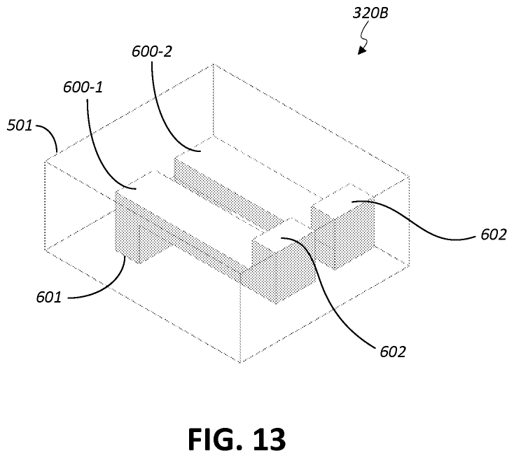

FIG. 13 shows a 3D transparent view of an inductor unit 320B, in accordance with an embodiment of the present invention. The inductor unit 320B is an implementation of the inductor unit 320 for a non-TLVR circuit topology (e.g., see FIG. 2). Instead of transformers, inductors 600 (i.e., 600-1, 600-2) are embedded in the magnetic core 501. Each of the inductors 600 is a single turn inductor. The inductor unit 320B is depicted as having two inductors 600 for illustration purposes only. Additional inductors 600 may be embedded within the magnetic core 501 to meet the needs of a particular application.

The inductor units 320A and 320B are essentially the same except that the inductor unit 320B has no secondary windings. In the example of FIG. 13, an inductor 600 has a first end 602 that is electrically connected to a contact pad on the top surface of the magnetic core 501 and a second end 601 that is electrically connected to a contact pad on the bottom surface of the magnetic core 501.

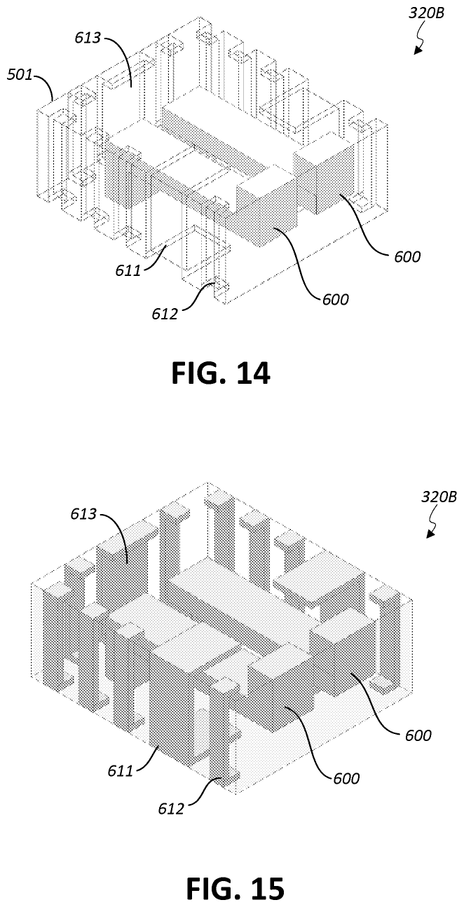

FIGS. 14 and 15 show additional 3D transparent views of the inductor unit 320B, in accordance with an embodiment of the present invention.

Referring to FIGS. 14 and 15, a via goes from the top surface to the bottom surface of the magnetic core 501. As an example, a via 611 electrically connects a ground reference from a contact pad on the top surface (see FIG. 5, GND contact pad) to a contact pad on the bottom surface (see FIG. 7, GND contact pad) of the magnetic core 501. As another example, a via 612 electrically connects an enable signal from a contact pad on the top surface (e.g., FIG. 5, EN2 contact pad) to a contact pad on the bottom surface (e.g., see FIG. 7, EN2 contact pad) of the magnetic core 501. Yet another example, a via 613 electrically connects the input voltage from a contact pad on the top surface (e.g., FIG. 5, contact pad 373) to a contact pad on the bottom surface (e.g., see FIG. 7, contact pad 423) of the magnetic core 501.

A power module may have one or more power blocks. As an example, a power module may have a single power block 300. As another example, four or more power blocks 300 may be packaged together to form a single power module.

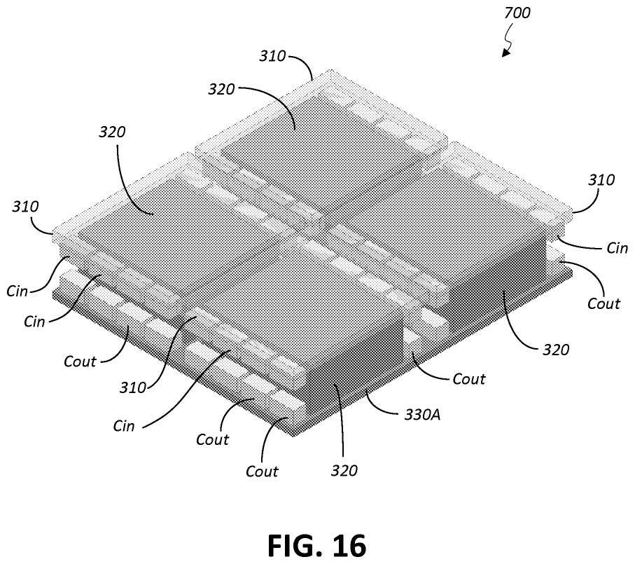

FIG. 16 shows a 3D transparent view of a power module 700 that comprises four power blocks 300, in accordance with an embodiment of the present invention. In the example of FIG. 16, the power blocks 300 are as previously described except that they all share the same underlying substrate 330, which is relabeled as 330A for clarity of illustration. That is, the inductor units 320 and substrates 310 of corresponding power blocks 300 are all disposed on the same underlying substrate 330A. As previously explained, the input capacitors Cin are disposed on the bottom sides of the substrates 310 and the output capacitors Cout are disposed on the top side of the underlying substrate 330A. Using the same underlying substrate 330A allows the power blocks 300 to form a single power module that can be added or removed as needed to meet particular power supply requirements. In the example of FIG. 16, given two phases per power block 300, the power module 700 allows 8 phases to be added to or removed from a power supply.

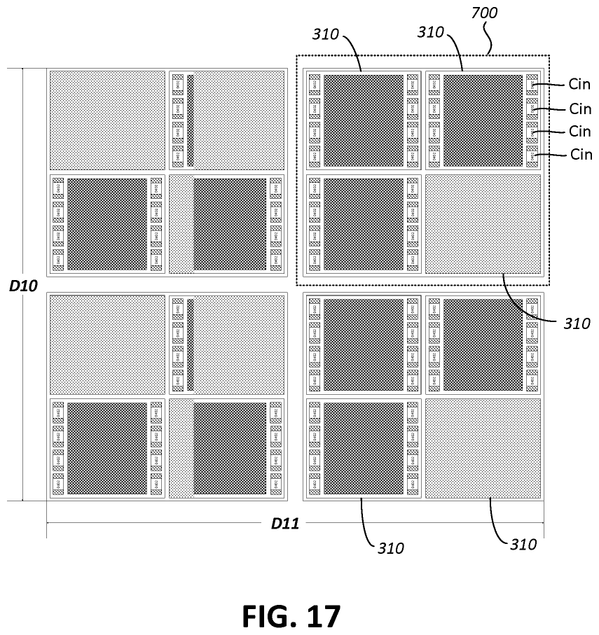

FIG. 17 shows a planar view of the bottom sides of the substrates 310 in the power module 700, in accordance with an embodiment of the present invention. In the example of FIG. 17, there are four instances of the power module 700, with each power module 700 having four power blocks 300. Given two phases per power block 300, a power supply that incorporates the layout of FIG. 17 can have 32 phases. A vertical dimension D10 is about 27.6 mm and a horizontal dimension D11 is about 31.6 mm in the embodiment where there are four power blocks 300 per power module 700. Packaging all 16 power blocks 300 on the same underlying substrate, i.e., a power module with 16 power blocks, will further reduce the vertical dimension D10 to about 26.8 mm and the horizontal dimension D11 to about 30.8 mm.

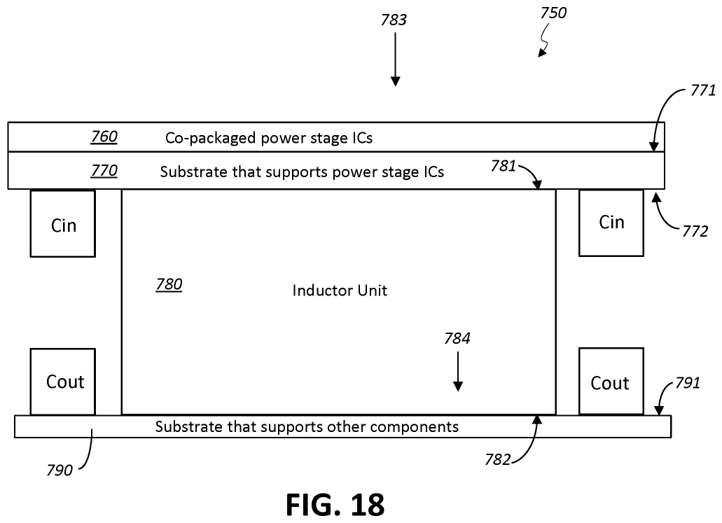

FIG. 18 shows a side view of a physical layout of a power block 750, in accordance with an embodiment of the present invention. FIG. 18 is not drawn to scale. The power block 750 may comprise the power converter 10 of FIG. 1, power converter 100 of FIG. 2, or other power converter. The power block 750 comprises a substrate 770 that supports a package 760 of co-packaged power stage ICs of the power converter, an inductor unit 780, and an underlying substrate 790 that supports other components of the power converter.

The power block 750 is similar to the power block 300 except that the power stage ICs are packaged together in the same package 760. This allows the power block 750 to have more phases. In one embodiment, each package 760 has four DrMOS dies, allowing for four phases per power block 750. Additional power stage ICs may be included in the package 760 to allow for more phases per power block.

In one embodiment, the substrate 770 is an IC substrate. The substrate 770 has a top side 771 and a bottom side 772. One or more input capacitors Cin are disposed on the bottom side 772, and the package 760 is disposed on the top side 771. An input capacitor Cin and an output capacitor Cout may be a 0201 capacitor, a 0402 capacitor, a 0603 capacitor, a 0805 capacitor, or other suitably sized capacitor. Placing the package 760 on the top side 771 advantageously improves heat dissipation. Furthermore, disposing the input capacitors Cin on the bottom side 772 allows more active components to be disposed on the top side 771, thereby improving the current density of the power block 750.

The inductor unit 780 is essentially the same as the inductor unit 320, except that the inductor unit 780 has more transformers or inductors embedded in the magnetic core to accommodate the higher number of power stage ICs. The inductor unit 780 has a top side 781 that interfaces with the bottom side 772 of the substrate 770 and a bottom side 782 that interfaces with the top side 791 of the underlying substrate 790. Embedded in the magnetic core of the inductor unit 780 are transformers or inductors (depending on the circuit topology of the power converter). Vias may be attached to or embedded within the magnetic core to electrically connect contact pads on the top side 781 to contact pads on the bottom side 782 of the inductor unit 780. In one embodiment, the magnetic core of the inductor unit 780 comprises a rectangular block of magnetic material, the top side 781 of the inductor unit 780 is the top surface of the magnetic core, and the bottom side 782 of the inductor unit 780 is the bottom surface of the magnetic core.

FIG. 18 also shows viewing reference arrows 783 and 784 that are referred to below. Note that the top side 791 of the underlying substrate 790 and the bottom side 772 of the substrate 770 are facing toward each other.

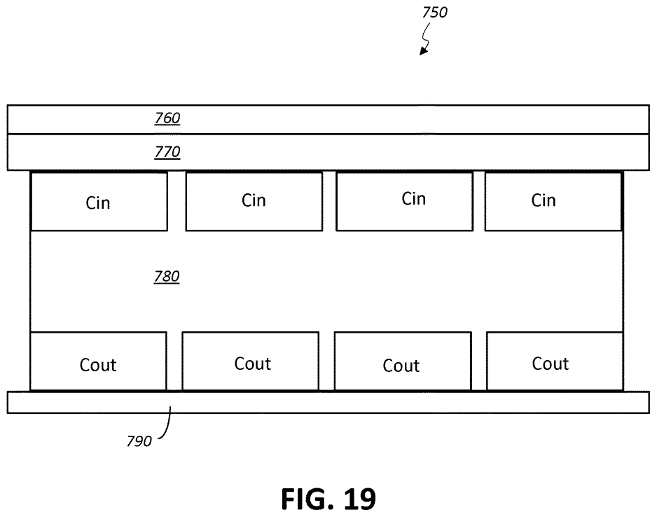

FIG. 19 shows a side view of the power block 750, in accordance with an embodiment of the present invention. As shown in FIG. 19, the input capacitors Cin are disposed along the perimeter on the bottom side of the substrate 770 and the output capacitors Cout are disposed along the perimeter on the top side of the underlying substrate 790.

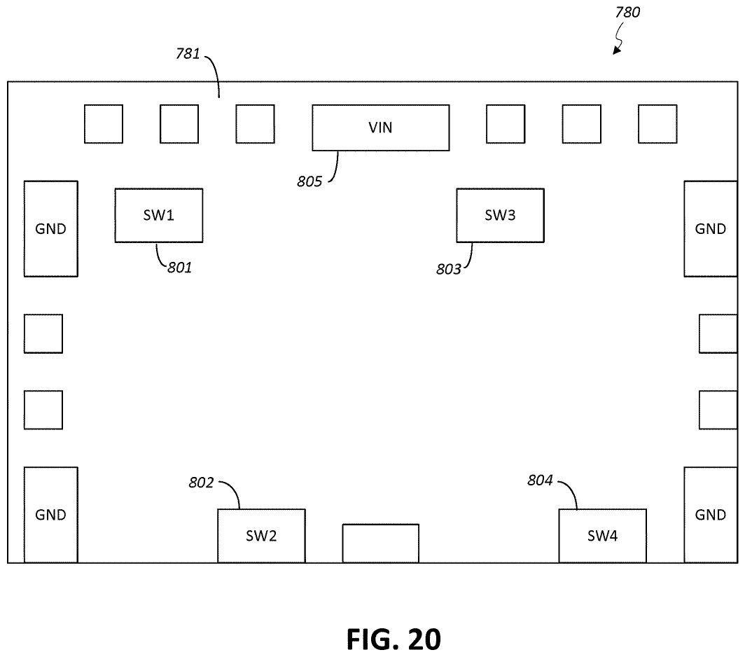

FIG. 20 shows a planar view of the top side 781 of the inductor unit 780, in accordance with an embodiment of the present invention.

FIG. 20 show contact pads of the inductor unit 780 that interface with corresponding contact pads on the bottom side 772 of the substrate 770 to electrically connect to corresponding nodes on the package 760. In the example of FIG. 20, the contact pads 801-804 electrically connect to corresponding switch nodes of power converters in the package 760. The contact pad 805 electrically connects to the input voltage VIN. Other contact pads on the top side 781 electrically connect to corresponding contact pads on the bottom side 782 by way of vias that are attached to or embedded within the inductor unit 780. As before, output inductors and primary windings that are embedded within the inductor unit 780 have ends that are on opposite sides of the inductor unit 780.

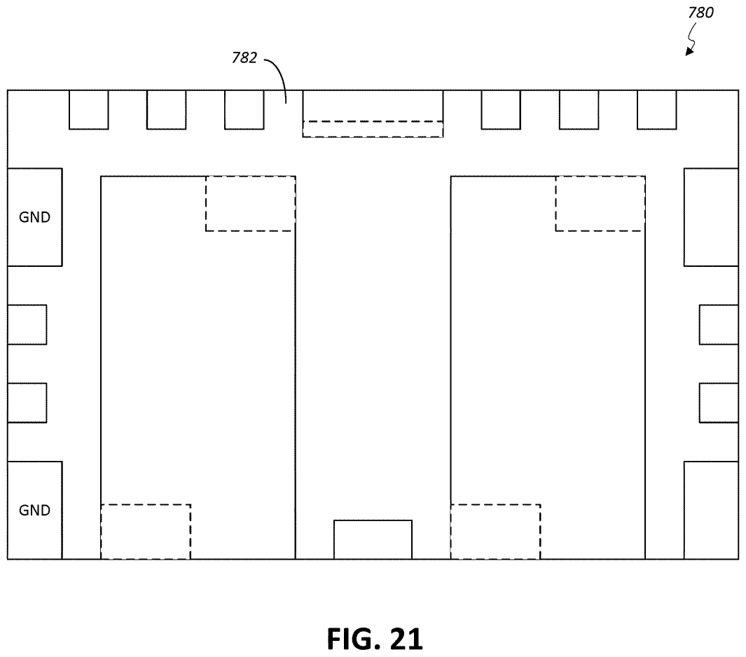

FIG. 21 shows a planar view of the bottom side 782 of the inductor unit 780, in accordance with an embodiment of the present invention. FIG. 21 shows the bottom side 782 as seen in the direction of the arrow 784 in FIG. 18, i.e., as seen from the top, with the package 760, substrate 770, and the rest of the inductor unit 780 being transparent. FIG. 21 shows contact pads on the bottom side 782 that interfaces with corresponding contact pads on the top side 791 of the underlying substrate 790 to electrically connect to corresponding nodes of circuits on the underlying substrate 790 or other substrate. In embodiments where the inductor unit 780 has embedded output inductors, one end of each the output inductors will have a corresponding contact pad on the bottom side 782. In embodiments where the inductor unit has an embedded transformer, one end of a primary winding of the transformer and both ends of a secondary winding of the transformer will have corresponding contact pads on the bottom side 782. Other contact pads on the bottom side 782 of the inductor unit 780 are connected by vias to corresponding contact pads on the top side 781 of the inductor unit 780.

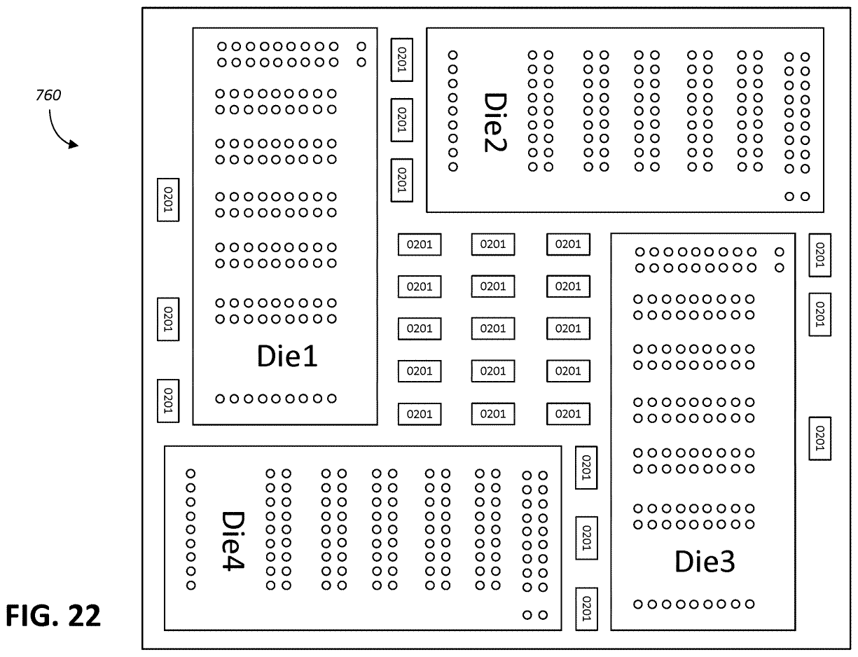

FIG. 22 shows a planar view of a top side of the package 760, in accordance with an embodiment of the present invention. FIG. 22 is as seen in the direction of arrow 783 shown in FIG. 18 with the rest of the package 760 and the substrate 770 being transparent to show the input capacitors Cin on the bottom side 772 of the substrate 770. FIG. 22 shows four DrMOS dies. The circles within the DrMOS dies represent nodes to circuits that are integrated in the DrMOS. Input capacitors Cin, which are 0201 capacitors in the example of FIG. 22, and other capacitors are disposed on the bottom side 772 of the substrate 770.

Power modules described herein may incorporate power blocks having an inductor unit that is molded or with an open-frame design (i.e., not molded). Molded inductor designs potentially provide good planarity on the top side and bottom side, which facilitates assembly. However, molded inductor designs pose their own set of problems.

More particularly, power modules may require a complex inductor unit design with contact pads exposed on the top side and bottom side of the magnetic core. Such magnetic core may have multiple windings (that serve as transformer windings or inductor coils) embedded within the core corresponding to the contact pads. When there are multiple inductor units in the power module, the number of contact pads increases.

One challenge to assemble such power modules is how to deal with the coplanarity of contact pads. The tolerance of contact pad height cannot be controlled well due to the hybrid molding and assembly process of inductor manufacturing. A grinding step may be employed to make the contact pads coplanar, and planarize the corresponding surface of the inductor unit. Molding compound may be used to protect the inductor unit during grinding. However, simply molding the inductor unit will fill all empty regions of the inductor layer with the molding compound. This will complicate placement of components in the inductor layer. For example, if the molding compound fills the entire lateral extent of the inductor layer, there may be insufficient space to accommodate capacitors and other components that are disposed adjacent to the inductor unit. As described in detail below, the molding compound may be shaped to include one or more cavities in regions adjacent to the inductor unit, the cavities being configured to receive components such as input capacitors and/or output capacitors.

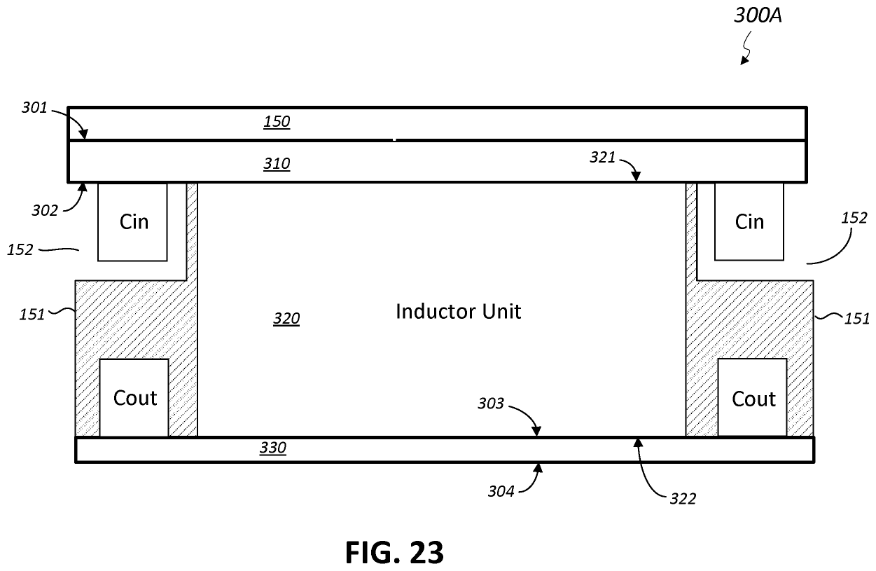

FIG. 23 shows a side view of a physical layout of a power block 300A, in accordance with an embodiment of the present invention. The power block 300A is a specific embodiment of the power block 300 described above with reference to FIG. 3. FIG. 23 is not drawn to scale.

In the present disclosure, the terms “upper”, “lower”, “top”, and “bottom” are used relative to a support substrate on which a power module incorporating the power block is disposed. The support substrate may be, for example, a motherboard or other circuit board that is powered by the power block.

The power block 300A comprises the previously-described substrates 310 and 330. The substrate 310 has the top side 301 and the bottom side 302. The substrate 330 has the top side 303 and the bottom side 304. The top side 303 of the substrate 330 faces the bottom side 302 of the substrate 310. The bottom side 304 of the substrate 330 faces the support substrate (not shown). In the example of FIG. 23, a package 150 houses co-packaged power stage ICs of the power converter. The package 150 is disposed on the top side 301 of the substrate 310. The package 150 comprises one or more power stage ICs.

In one embodiment, input capacitors Cin are disposed on the bottom side 302 of the substrate 310, and output capacitors Cout are disposed on the top side 303 of the substrate 330. The input capacitors Cin and the output capacitors Cout are disposed in regions adjacent to the inductor unit 320, along the perimeter of the power block 300A.

The inductor unit 320 is disposed between the substrates 310 and 330, in a region referred to herein as the inductor layer. The inductor unit 320 comprises a magnetic core, and windings embedded with the magnetic core. As used herein, the term “winding” refers to either a transformer winding or inductor coil. The inductor unit 320 includes contact pads on its top side 321 and bottom side 322, as described above with reference to FIGS. 5-7.

A molding compound 151 is disposed in the inductor layer and at least partially encapsulates the inductor unit 320. In one embodiment, the molding compound 151 surrounds the inductor unit 320 within the inductor layer. The top side 321 and bottom side 322 of the inductor unit 320 are not covered by the molding compound 151, such that the contact pads on the top side 321 and bottom side 322 are exposed for electrical connection to the substrate 310 and the substrate 330, respectively. The cavities 152 are formed in the molding compound 151 on two opposing sides of the inductor unit 320, and are configured to receive components, such as capacitors. In the example of FIG. 23, on each of the two opposing sides of the inductor unit 320, a first set of capacitors is embedded within the molding compound 151 and a second set of capacitors is disposed in the cavities 152. In the example of FIG. 23, the input capacitors Cin are disposed in the cavities 152 and the output capacitors Cout are embedded in the molding compound 151. In one embodiment, the cross-sectional profile of the molding compound 151 is substantially T-shaped.

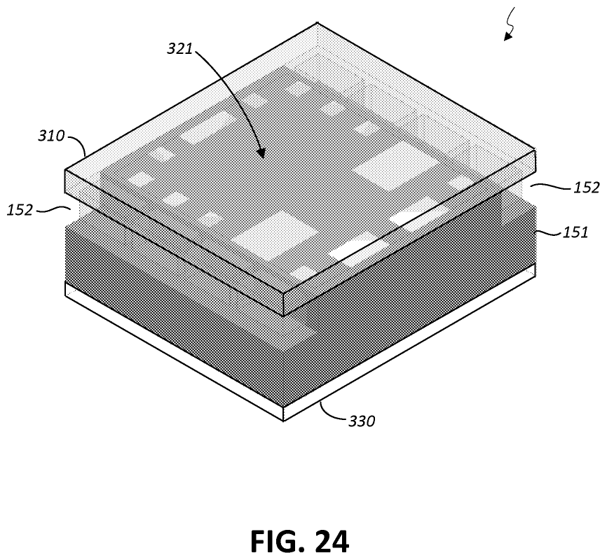

FIG. 24 shows a 3D view of the power block 300A, in accordance with an embodiment of the present invention. FIG. 24 does not show the package 150, and depicts the substrate 310 as transparent to show the contact pads on the top side 321 of the inductor unit 320. In one embodiment, the inductor unit 320 has four sides, and the cavities 152 are along two, opposing sides; the other two opposing sides do not have cavities 152. The cavities 152 are in the inductor layer, between the molding compound 151 and the bottom side 302 of the substrate 310 to accommodate the capacitors Cin.

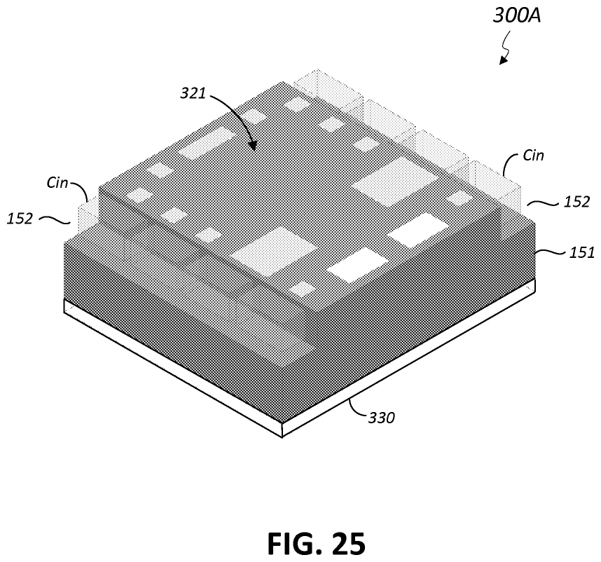

FIG. 25 shows a 3D view of the power block 300A, in accordance with an embodiment of the present invention. FIG. 25 does not show the package 150 and the substrate 310 to better show the capacitors Cin and the top side 321 of the inductor unit 320.

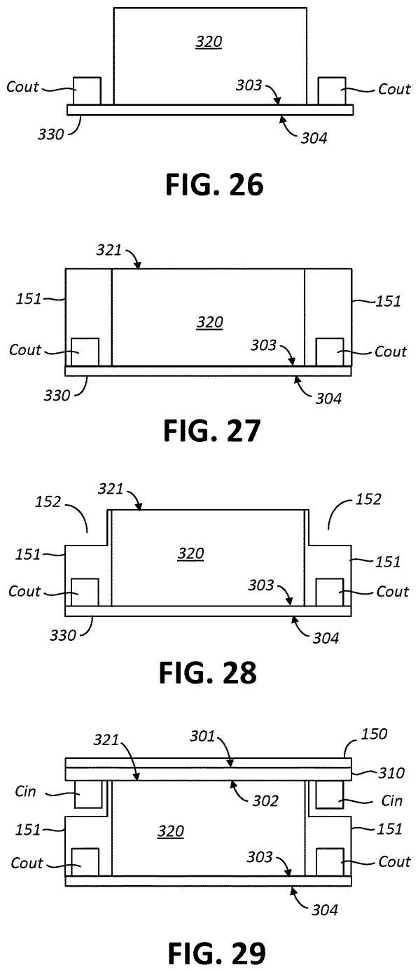

FIGS. 26-29 are side views illustrating a method of manufacturing the power block 300A, in accordance with an embodiment of the present invention.

In FIG. 26, the substrate 330 comprises a printed circuit board (PCB), and the inductor unit 320 and the output capacitors Cout are mounted on the top side 303 of the substrate 330 by surface mount technology (SMT). The bottom side 304 of the substrate 330 is labeled for reference.

In FIG. 27, following FIG. 26, a molding step is performed to encapsulate the inductor unit 320 and the capacitors Cout in the molding compound 151. Following the molding step, a grinding step is performed to grind down the molding compound 151 to the top side 321 of the inductor unit 320, thereby planarizing the surface and exposing the contact pads on the top side 321.

In FIG. 28, following FIG. 27, the cavities 152 are formed in the molding compound 151 on two opposing sides of the inductor unit 320. The cavities 152 may be formed, for example, by drilling into the molding compound 151. The cavities 152 provide an open space to receive capacitors or other components.

In another embodiment, the cavities 152 are formed during the molding step itself, using a mold that defines the shape of the cavities 152. Following the molding step, the grinding step is performed to planarize the surface and expose the contact pads on the top side 321 of the inductor unit 320. The remaining steps of the manufacturing process are the same as those described above with reference to FIGS. 26-29, except that the separate drilling step is not required.

In FIG. 29, following FIG. 28, the substrate 310 comprising a PCB is assembled onto the inductor unit 320 by SMT, thereby attaching the bottom side 302 of the substrate 310 to the top side 321 of the inductor unit 320. In one embodiment, the substrate 310 already has the package 150 mounted on the top side 301 and the input capacitors Cin mounted on the bottom side 302 before the substrate 310 is attached to the inductor unit 320, thereby receiving the input capacitors Cin in the cavities 152.

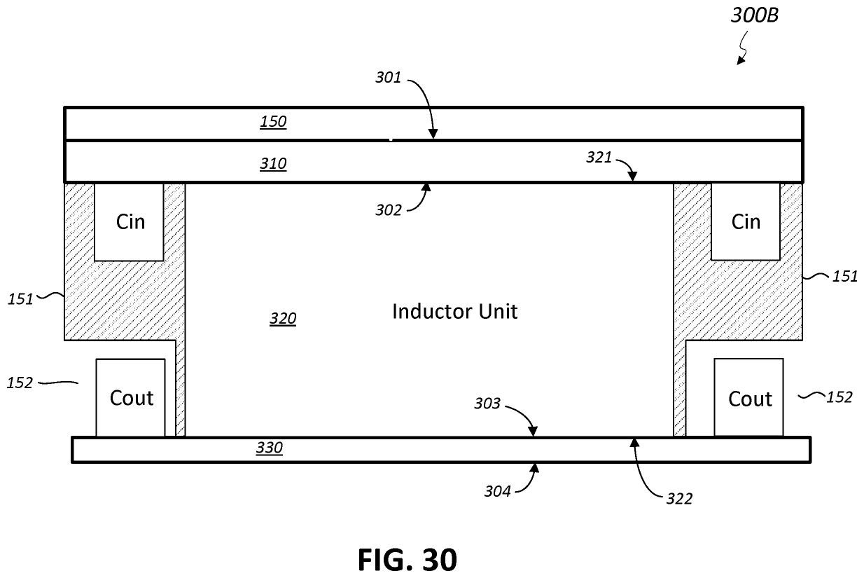

FIG. 30 shows a side view of a physical layout of a power block 300B, in accordance with an embodiment of the present invention. The power block 300B is similar to the power block 300A of FIG. 23, except that the orientation of the molding compound 151 is reversed. FIG. 30 is not drawn to scale.

In the power block 300B, the cavities 152 open toward the top side 303 of the lower substrate 330, and the output capacitors Cout are disposed in the cavities 152. The input capacitors Cin are embedded in the molding compound 151.

The manufacturing process for the power block 300B may be similar to that described above with reference to FIGS. 26-29 to form the cavities 152. For example, the power block 300B may be manufactured as in FIGS. 26-29, except that the substrate 310 with the input capacitors Cin is the starting substrate for the molding step, and the substrate 330 with the output capacitors Cout is assembled last, with the output capacitors Cout being received in the cavities 152.

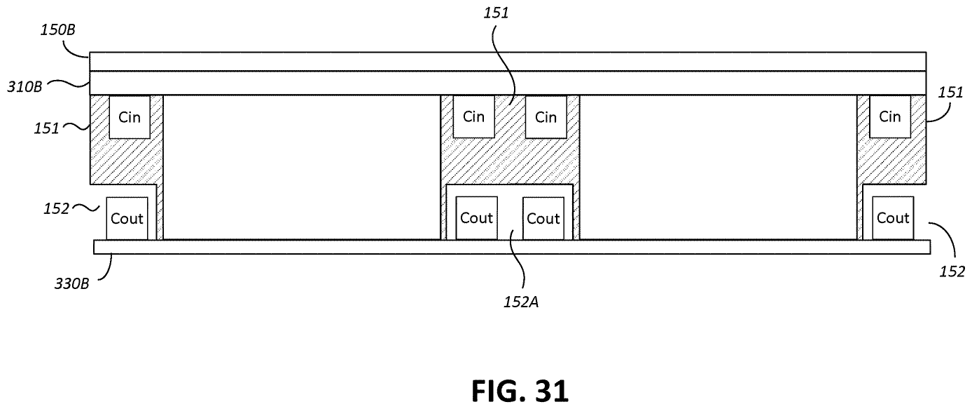

FIG. 31 shows a side view of a physical layout of a power module comprising two or more power blocks 300B that are disposed side-by-side, in accordance with an embodiment of the present invention. The power module of FIG. 31 may comprise four power blocks 300B arranged in 2×2 configuration, similar to the configuration shown in FIG. 16 for example. The power blocks 300B share a common substrate 310B and a common substrate 330B, which are larger versions of the substrates 310 and 330, respectively. A common package 150B, which is a larger version of the package 150, is disposed on the substrate 310B. A common cavity 152A is formed between adjacent power blocks 300B in the molding compound 151, the common cavity 152A may receive two or more rows of output capacitors Cout.

In another embodiment, a power module may comprise two or more power blocks 300A, with common cavities formed between adjacent power blocks for receiving input capacitors Cin.

High current density power modules have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A power block of a power converter, the power block comprising:
a first substrate having a first side and a second side;
one or more power stage integrated circuits disposed on the first side of the first substrate;
a second substrate having a first side and a second side, the first side of the second substrate facing the second side of the first substrate;
an inductor unit comprising a magnetic core and a winding embedded within the magnetic core, the inductor unit being disposed between the first substrate and the second substrate, the winding having a first end that is electrically connected to one of a plurality of contact pads on a first side of the inductor unit that interfaces with the first substrate and a second end that is electrically connected to one of a plurality of contact pads on a second side of the inductor unit that interfaces with the second substrate;
a molding compound disposed between the first and second substrates and at least partially encapsulating the inductor unit, the molding compound having one or more cavities in regions adjacent to the inductor unit;
a first set of components embedded in the molding compound; and
a second set of components disposed in the one or more cavities.

2. The power block of claim 1, wherein the first set of components comprises capacitors that are disposed on the first side of the second substrate and the second set of components comprises capacitors that are disposed on the second side of the first substrate.

3. The power block of claim 2, wherein the first set of components comprises output capacitors and the second set of components comprises input capacitors.

4. The power block of claim 1, wherein the first set of components comprises capacitors that are disposed on the second side of the first substrate and the second set of components comprises capacitors that are disposed on the first side of the second substrate.

5. The power block of claim 4, wherein the first set of components comprises input capacitors and the second set of components comprises output capacitors.

6. The power block of claim 1, wherein the one or more power stage integrated circuits comprise a pair of switches, the winding is a first output inductor, the first end is electrically connected to a switch node of the pair of switches, and the second end is electrically connected to an output voltage node of the power converter.

7. The power block of claim 1, wherein the cavities are on two opposing sides of the inductor unit.

8. The power block of claim 1, wherein a cross-sectional profile of the molding compound is substantially T-shaped.

9. A method of manufacturing a power block of a power converter, the method comprising:
mounting an inductor unit and a first set of components on a first side of a first substrate, the inductor unit comprising a magnetic core and a winding embedded within the magnetic core;
encapsulating the inductor unit and the first set of components in a molding compound;
grinding down the molding compound to a first side of the inductor unit, thereby planarizing a surface of the molding compound and exposing contact pads on the first side of the inductor unit;
forming one or more cavities in the molding compound in regions adjacent to the inductor unit; and
assembling a second substrate onto the inductor unit, the second substrate having a second set of components disposed thereon, the second set of components being received in the one or more cavities,
wherein one or more power stage integrated circuits are disposed on one of the first substrate and the second substrate.

10. The method of claim 9, wherein the one or more power stage integrated circuits are disposed on the second substrate.

11. The method of claim 9, wherein the one or more power stage integrated circuits are disposed on the first substrate.

12. The method of claim 9, wherein forming the one or more cavities comprises drilling into the molding compound.

13. The method of claim 9, wherein the one or more cavities are formed during a molding step using a mold that defines a shape of the one or more cavities.

14. The method of claim 13, wherein the grinding step is performed after the molding step.

15. The method of claim 9, wherein the first set of components comprises output capacitors and the second set of components comprises input capacitors.

16. The method of claim 9, wherein the first set of components comprises input capacitors and the second set of components comprises output capacitors.

17. The method of claim 9, wherein the cavities are formed on two opposing sides of the inductor unit.

18. A power module comprising:
a first substrate having a first side and a second side;
one or more power stage integrated circuits disposed on the first side of the first substrate;
a second substrate having a first side and a second side, the first side of the second substrate facing the second side of the first substrate;
two or more inductor units disposed between the first substrate and the second substrate, each of the two or more inductor units comprising a magnetic core and a winding embedded within the magnetic core;
a molding compound disposed between the first and second substrates and at least partially encapsulating the two or more inductor units, the molding compound having one or more cavities in regions adjacent to the two or more inductor units;
a first set of components embedded in the molding compound; and
a second set of components disposed in the one or more cavities.

19. The power module of claim 18, wherein adjacent inductor units share a common cavity in the molding compound.

20. The power module of claim 19, wherein the common cavity has at least two rows of capacitors.
